(19) United States
(12) Patent Application Publication
(10) Pub. No.: US 2004/0069223 A1
(43) Pub. Date: Apr. 15, 2004

(54) Wall liner and slot liner for process chamber

(75) Inventors: Huan-Liang Tzeng, Hsinchu (TW); Jung-Hsiang Chang, Hsin-Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/268,265

(22) Filed: Oct. 10, 2002

(51) Int. Cl. H01L 21/306; C23C 16/00

(52) U.S. Cl. 118/715; 156/345.1

(57) ABSTRACT

A chamber liner which includes a wall liner for protecting the interior wall surfaces of a process chamber from deposition of polymer contaminants thereon during a semiconductor fabrication process carried out in the chamber and a slot liner for protecting a wafer slot in the chamber from deposition of the polymer contaminants. The wall liner typically comprises a cylindrical liner wall that may be interrupted by an elongated slit to facilitate compressing the liner and placing the liner in the process chamber. Once positioned in the process chamber, the wall liner expands against the interior wall surfaces of the chamber. The slot liner is inserted through the wafer slot in the process chamber and communicates with a slot liner opening in the wall liner. Wafers are transferred into and out of the chamber through the slot liner.

### FIELD OF THE INVENTION

The present invention relates to processes for fabricating integrated circuits on a semiconductor wafer. More particularly, the invention relates to a chamber liner which includes a wall liner that may be removably fitted in a process chamber such as an etcher and a slot liner that may be removably fitted in a wafer slot in the chamber, to prevent deposition of polymer materials on the interior chamber walls and the wafer slot of the chamber particularly during an STI (shallow trench isolation) process carried out in the chamber.

### BACKGROUND OF THE INVENTION

Integrated circuits are formed on a semiconductor substrate, which is typically composed of silicon. Such formation of integrated circuits involves sequentially forming or depositing multiple electrically conductive and insulative layers in or on the substrate. Etching processes may then be used to form geometric patterns in the layers or vias for electrical contact between the layers. Etching processes include “wet” etching, in which one or more chemical reagents are brought into direct contact with the substrate, and “dry” etching, such as plasma etching.

Various types of plasma etching processes are known in the art, including plasma etching, reactive ion (RI) etching and reactive ion beam etching. In each of these plasma processes, a gas is first introduced into a reaction chamber and then plasma is generated from the gas. This is accomplished by dissociation of the gas into ions, free radicals and electrons by using an RF (radio frequency) generator, which includes one or more electrodes. The electrodes are accelerated in an electric field generated by the electrodes, and the energized electrons strike gas molecules to form additional ions, free radicals and electrons, which strike additional gas molecules, and the plasma eventually becomes self-sustaining. The ions, free radicals and electrons in the plasma react chemically with the layer material on the semiconductor wafer to form residual products which leave the wafer surface and thus, etch the material from the wafer.

Etching is commonly used in a process known as shallow trench isolation (STI), which involves depositing a silicon nitride (S₃N₄) mask on a wafer. The mask is deposited and patterned, after which the silicon is etched in the wafer to form a trench. The areas on the wafer exposed through the mask are then oxidized to form a thick oxide layer which passivates the silicon surface and serves as a barrier between the silicon and the deposited trench-fill oxide. The oxide layer further serves as a barrier which prevents sidewall leakage in finished devices.

Referring to the schematic of FIG. 1, a conventional plasma etching system, such as an Applied Materials decoupled plasma source (DPS) poly chamber, is generally indicated by reference numeral 10. The etching system 10 includes a reaction chamber 12 having a typically grounded chamber wall 14. An electrode 16 is positioned adjacent to a dielectric plate 18 which separates the electrode 16 from the interior of the reaction chamber 12. Plasma-generating source gases are provided by a gas supply (not shown). Volatile reaction products and unreacted plasma species are removed from the reaction chamber 12 by a gas removal mechanism, such as a vacuum pump (not shown).

The dielectric plate 18 illustrated in FIG. 1 may serve multiple purposes and have multiple structural features, as is well known in the art. For example, the dielectric plate 18 may include features for introducing the source gases into the reaction chamber 12, as well as those structures associated with physically separating the electrode 16 from the interior of the chamber 12.

Electrode power such as a high voltage signal, provided by a power generator such as an RF (radio frequency) generator (not shown), is applied to the electrode 16 to ignite and sustain a plasma in the reaction chamber 12. Ignition of a plasma in the reaction chamber 12 is accomplished primarily by electrostatic coupling of the electrode 16 with the source gases, due to the large-magnitude voltage applied to the electrode 16 and the resulting electric fields produced in the reaction chamber 12. Once ignited, the plasma is sustained by electromagnetic induction effects associated with time-varying magnetic fields produced by the alternating currents applied to the electrode 16. The plasma may become self-sustaining in the reaction chamber 12 due to the generation of energized electrons from the source gases and striking of the electrons with gas molecules to generate additional ions, free radicals and electrons. A semiconductor wafer 24 is positioned in and removed from the reaction chamber 12 typically through a wafer slot 28 in the chamber wall 14, and is supported by an electrostatic chuck 22 provided above a cathode 20.

In the DPS poly etcher 10, the power supply is separated into a source power and a bias power. The source power is high power supplied to the electrode 16. The bias power, or “bottom” power, is applied to the wafer 24 through the cathode 20. The source power ionizes the gas supplied into the chamber and generates the reactive species in the chamber. The bias power on the wafer drives reactive species to accelerate the reactions. Hence, a greater degree of control over the etching process is facilitated since the source power controls generation of the chemical species and thus, the chemical etch portion, whereas the bias power controls the physical part of the etch, which encompasses bombardment of the ionic species into the wafer.

The plasma generated and sustained in the reaction chamber includes high-energy ions, free radicals and electrons which react chemically with the surface material of the semiconductor wafer to form reaction produces that leave the wafer surface, thereby etching a geometrical pattern or a via in a wafer layer. Plasma intensity depends on the type of etchant gas or gases used, as well as the etchant gas pressure and temperature and the radio frequency generated at the electrode 16. If any of these factors changes during the process, the plasma intensity may increase or decrease with respect to the plasma intensity level required for optimum etching in a particular application. Decreased plasma intensity results in decreased, and thus incomplete, etching. Increased plasma intensity, on the other hand, can cause overetching and plasma-induced damage of the wafers. Plasma-induced damage includes trapped interface charges, material defects migration into bulk materials, and contamination caused by the deposition of etch products on material surfaces. Etch damage induced by reactive plasma can alter the qualities of sensitive IC components such as Schottky diodes, the rectifying capability of which can be reduced considerably. Heavy-polymer deposition during oxide contact hole etching may cause high-contact resistance.

In semiconductor production, the quality of the integrated circuits on the semiconductor wafer is directly correlated with the purity of the fabricating processes, which in turn depends upon the cleanliness of the manufacturing environment. Furthermore, technological advances in recent years in the increasing miniaturization of semiconductor circuits necessitate correspondingly stringent control of impurities and contaminants in the plasma process chamber. When the circuits on a wafer are submicron in size, the smallest quantity of contaminants can significantly reduce the yield of the wafers. For instance, the presence of particles during deposition or etching of thin films can cause voids, dislocations, or short-circuits which adversely affect performance and reliability of the devices constructed with the circuits.

Particle and film contamination has been significantly reduced in the semiconductor industry by improving the quality of clean rooms, by using automated equipment designed to handle semiconductor substrates, and by improving techniques used to clean the substrate surfaces. However, as deposit of polymer material 26 on the interior surfaces of the reaction chamber 12 remains a problem, various techniques for in-situ cleaning of process chambers have been developed in recent years. Cleaning gases such as nitrogen trifluoride, chlorine trifluoride, hexafluoroethane, sulfur hexafluoride and carbon tetrafluoride and mixtures thereof have been used in various cleaning applications. These gases are introduced into a process chamber at a predetermined temperature and pressure for a desirable length of time to clean the surfaces inside a process chamber. However, these cleaning techniques are not always effective in cleaning or dislodging all the film and particle contaminants coated on the chamber walls. The smallest quantity of contaminants remaining in the chamber after such cleaning processes can cause significant problems in subsequent manufacturing cycles.

Accordingly, an object of the present invention is to provide a liner for the interior surfaces of a process chamber.

Another object of the present invention is to provide a liner which may be removably fitted inside a process chamber to prevent polymer contaminants from accumulating on the interior surfaces of the chamber.

Still another object of the present invention is to provide a chamber liner for a process chamber, which chamber liner may be periodically removed from the chamber for cleaning and replaced in the chamber.

A still further object of the present invention is to provide a chamber liner which includes a slot liner that may be removably fitted in a wafer slot in a process chamber to prevent deposition of polymers in the slot during a process carried out in the chamber.

Yet another object of the present invention is to provide a chamber liner which includes a slitted wall liner which may be removably fitted in a process chamber to prevent deposition of polymer contaminants on the interior surfaces of the process chamber walls and a slot liner which may be removably fitted in a wafer slot in the process chamber to prevent deposition of polymer contaminants in the wafer slot, which wall liner and slot liner may be periodically removed from the chamber for cleaning purposes.

A still further object of the present invention is to provide a chamber liner which is particularly suitable for DPS poly chambers.

Yet another object of the present invention is to provide a chamber liner which may be adapted to accommodate a variety of process chambers for semiconductor processing.

### SUMMARY OF THE INVENTION

In accordance with these and other objects and advantages, the present invention is generally directed to a chamber liner which includes a wall liner for protecting the interior wall surfaces of a process chamber from deposition of polymer contaminants thereon during a semiconductor fabrication process carried out in the chamber and a slot liner for protecting a wafer slot in the chamber from deposition of the polymer contaminants. The wall liner typically comprises a cylindrical liner wall that may be interrupted by an elongated slit to facilitate compressing the liner and placing the liner in the process chamber. Once positioned in the process chamber, the wall liner expands against the interior wall surfaces of the chamber. The slot liner is inserted through the wafer slot in the process chamber and communicates with a slot liner opening in the wall liner. Wafers are transferred into and out of the chamber through the slot liner.

### BRIEF DESCRIPTION OF THE DRAWINGS

The invention will now be described, by way of example, with reference to the accompanying drawings, in which:

FIG. 1 is a cross-sectional view of a conventional process chamber suitable for implementation of the present invention;

FIG. 2 is a rear view of an illustrative embodiment of the wall liner component of the chamber liner of the present invention;

FIG. 3 is a front view of an illustrative embodiment of the wall liner component of the chamber liner of the present invention;

FIG. 4 is a top exploded view of the chamber liner;

FIG. 4A is a top view, partially in section, of the wall liner element of the chamber liner of the present invention, more particularly illustrating diametric compression of the wall liner to facilitate installation of the wall liner in a process chamber;

FIG. 5 is a front view of an illustrative embodiment of the slot liner component of the chamber liner of the present invention;

FIG. 5A is a cross-sectional view, taken along section lines 5-5 in FIG. 5, of the slot liner component of the chamber liner of the present invention;

FIG. 6 is a top view of a process chamber, with the lid components removed from the process chamber and a chamber liner of the present invention fitted in the process chamber;

FIG. 7 is a cross-sectional view, taken along section lines 7-7 in FIG. 6, of the process chamber and the chamber liner of the present invention fitted therein;

FIG. 8 is a bottom exploded view of an illustrative embodiment of the chamber liner of the present invention; and

FIG. 9 is a perspective view of an illustrative embodiment of the chamber liner of the present invention.

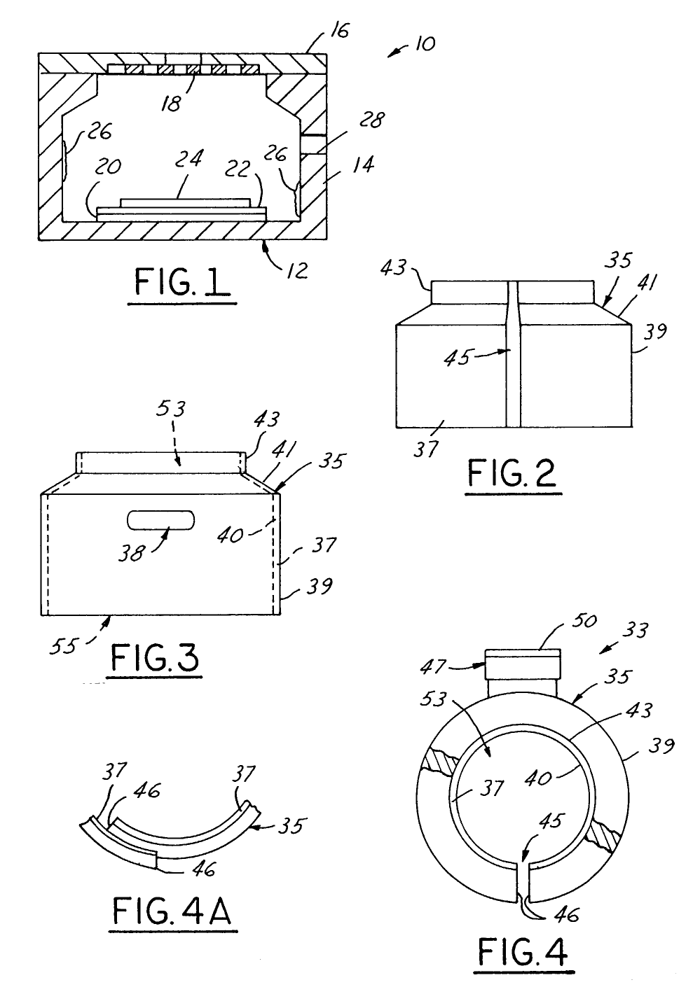

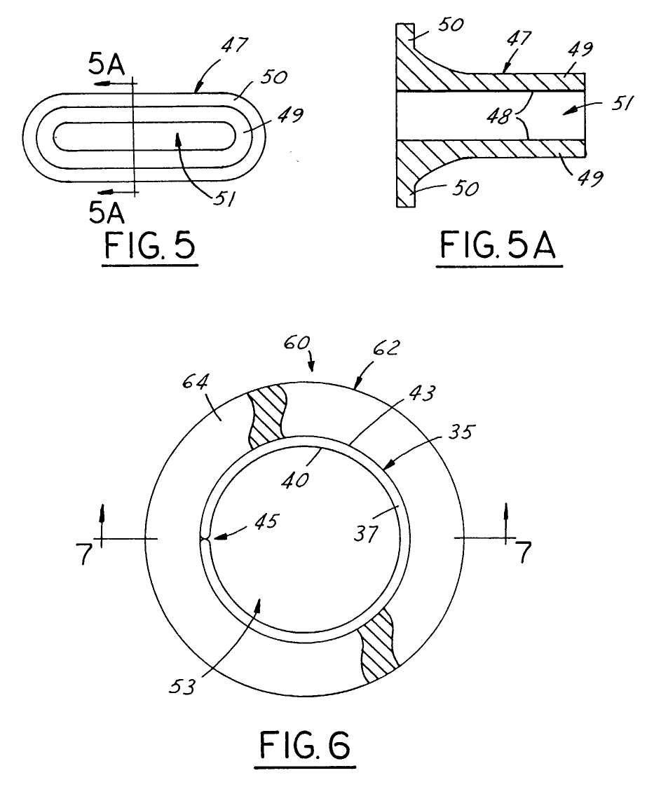

### DESCRIPTION OF THE PREFERRED EMBODIMENTS

The present invention has particularly beneficial utility in the prevention of polymer deposition on the interior wall surfaces of process chambers in the fabrication of semiconductor integrated circuits, particularly STI (shallow trench isolation) processes conducted in an Applied Materials DPS poly chamber. However, the invention is not so limited in application, and while references may be made to such semiconductors and DPS poly chambers, it is understood that the present invention is more generally applicable to prevention of polymer deposition in a variety of process chambers used in the fabrication of semiconductor integrated circuits, as well as in other industrial processes.

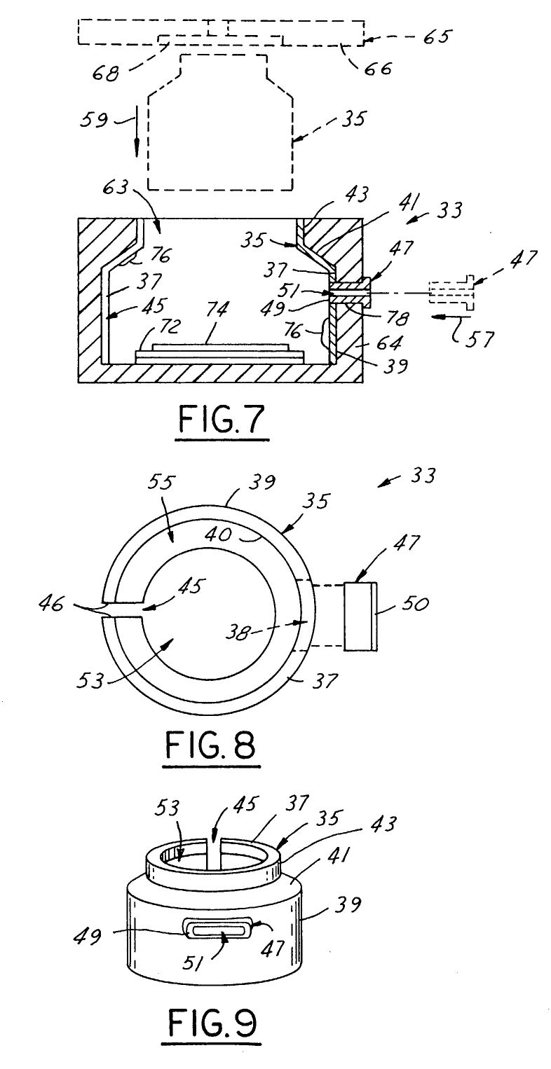

An illustrative embodiment of the chamber liner 33 of the present invention is shown in FIG. 4 and includes a wall liner 35 and a slot liner 47. The chamber liner 33 of the present invention is particularly adapted for use with a process chamber 62 (FIG. 7) for semiconductor fabrication, as hereinafter described. The process chamber 62 may be an Applied Materials DPS (decoupled plasma source) poly chamber, for example, or any of a variety of process chambers used in the semiconductor fabrication industry.

The wall liner 35 of the chamber liner 33 includes a generally cylindrical liner wall 37 which typically comprises aluminum having an anodized interior surface 40. In a preferred embodiment, the liner wall 37 has a thickness of from about 1 mm to about 3 mm, and preferably, about 1.5 mm. The liner wall 37 may define a wide base portion 39, a tapered portion 41 and a neck 43 to achieve a congruent fit with the interior wall contour of the process chamber 60, as shown in FIG. 7, such as an Applied Materials DPS poly chamber. In that case, the neck 43 typically has a diameter of about 44 cm., whereas the base portion 39 typically has a diameter of about 50 cm. However, it is understood that the liner wall 37 may alternatively have any desired contour and dimensions for congruently fitting the interior wall surface of any other type of process chamber in implementation of the present invention. The liner wall 37 defines a top opening 53 at the neck 43 thereof and a bottom opening 55 at the base 39 thereof. A vertical slit 45 typically interrupts the entire liner wall 37 to facilitate compressing the diameter of the wall liner 35 and placement of the wall liner 35 into the process chamber as hereinafter further described. As shown in FIG. 3, an elongated slot liner opening 38 typically extends through the liner wall 37 for purposes which will be hereinafter described. As shown in FIG. 8, the slot liner opening 38 may be diametrically-spaced from the slit 45 in the liner wall 37, or alternatively, disposed adjacent to the slit 45 or in any other position with respect to the slit 45. The slot liner opening 38 is disposed in such a vertical position in the liner wall 37 that the slot liner opening 38 is aligned with a wafer slot 78 (FIG. 7) of the process chamber 60 when the wall liner 35 is installed in functional position inside the process chamber 60.

As shown in FIGS. 5 and 5A, the slot liner 47 of the chamber liner 33 of the present invention typically has an elongated, elliptical configuration when viewed from the front, as shown in FIG. 5. The slot liner 47 includes a typically aluminum slot liner wall 49 which defines a wafer slot 51 and may have an anodized interior surface 48. The wafer slot 51 typically has an elongated, elliptical configuration, as shown in FIG. 5, and traverses the front-rear dimension of the slot liner 47, as shown in FIG. 5A. A slot liner flange 50 may be provided in the rear end of the slot liner 47.

Referring next to FIGS. 4, 4A and 7, in typical application the chamber liner 33 of the present invention is suitable for preventing deposit of polymer residues on the interior surfaces of the process chamber 62. Accordingly, the two-component chamber liner 33 is typically installed in the process chamber 62 as follows. First, as shown in FIG. 7, the slot liner 47 of the chamber liner 33 is inserted through the wafer slot 78 in the chamber wall 64 of the process chamber 62, as indicated by the arrow 57, until the slot liner flange 50 contacts the exterior surface of the chamber wall 39. Accordingly, the slot liner wall 49 extends across the entire thickness of the chamber wall 64 and protrudes into the interior of the process chamber 62. Next, the wall liner 35 of the chamber liner 33 is installed in the process chamber 62. This is accomplished by initially diametrically compressing the liner wall 37 on opposite sides of the vertical slit 45, as indicated by the arrows in FIG. 4. Accordingly, the slit edges 46 are capable of sliding past each other, as shown in FIG. 4A, to the extent that the diameter of the deformed wall liner 35 is sufficiently reduced to enable insertion of the wall liner 35 through the upper opening 63 of the process chamber 62. Simultaneously, the wall liner 35 is pushed downwardly into the process chamber 62, as indicated by the arrow 59 in FIG. 7. When the bottom edge of the wall liner 35 reaches the bottom of the process chamber 62, the liner wall 37 is released and expands outwardly to engage the inner surfaces of the chamber wall 64 and snugly fit the wall liner 35 in place in the process chamber 62. The slot liner opening 38 (FIG. 3) in the liner wall 37 receives the protruding end of the slot liner 47, as shown in FIG. 7. Finally, the chamber lid assembly 65, which typically includes an electrode 66 and a dielectric plate 68, is fitted on the process chamber 62, in conventional fashion. A semiconductor wafer 74 is laced in and removed from the process chamber 62 by operation of a wafer transfer robot (not shown), in conventional fashion, through the wafer slot 51 of the slot liner 47.

During operation of the process chamber 62, such as, for example, during the implementation of STI (shallow trench isolation) on a semiconductor wafer 74 supported on an ESC (electrostatic chuck) 72 inside the process chamber 62, processes such as etching of isolation trenches (not shown) in the wafer 74 and filling in of the trenches with a silicon oxide (not shown) are carried out in the process chamber 62. These processes cause the formation of polymer material 76 on the inside anodized surface of the wall liner 35 and on the inside anodized surface of the slot liner wall 49 of the slot liner 47. Accordingly, the cleaning process for removing the polymer material 76, implemented typically during periodic cleaning and maintenance (PM) between process cycles, is applied to the liner wall 37 and to the slot liner wall 49 rather than to the interior wall surfaces of the process chamber 62. Consequently, the interior surfaces of the chamber wall 64 remain free of the polymer material 76 and are not damaged or contaminated by the cleaning process. Moreover, the wall liner 35 may be removed from the process chamber 62 and cleaned or replaced, as needed.

While the preferred embodiments of the invention have been described above, it will be recognized and understood that various modifications can be made in the invention and the appended claims are intended to cover all such modifications which may fall within the spirit and scope of the invention.

What is claimed is:

1. A chamber liner for a process chamber having a chamber wall, said chamber liner comprising:
a wall liner having a liner wall for engaging the chamber wall.

2. The chamber liner of claim 1 wherein said liner wall has a thickness of about 1 mm to about 3 mm.

3. The chamber liner of claim 1 further comprising a slit interrupting said liner wall.

4. The chamber liner of claim 3 wherein said liner wall has a thickness of about 1 mm to about 3 mm.

5. The chamber liner of claim 1 further comprising a slot liner having a slot liner wall for engaging a wafer slot in the chamber wall adjacent to said wall liner.

6. The chamber liner of claim 5 wherein said liner wall of said wall liner has a thickness of about 1 mm to about 3 mm.

7. The chamber liner of claim 5 further comprising a slit interrupting said liner wall of said wall liner.

8. The chamber liner of claim 7 wherein said liner wall of said wall liner has a thickness of about 1 mm to about 3 mm.

9. The chamber liner of claim 1 wherein said liner wall comprises anodized aluminum.

10. The chamber liner of claim 9 wherein said liner wall has a thickness of about 1 mm to about 3 mm.

11. The chamber liner of claim 10 further comprising a slit interrupting said liner wall of said wall liner.

12. The chamber liner of claim 11 further comprising a slot liner having a slot liner wall for engaging a wafer slot in the chamber wall adjacent to said wall liner.

13. A chamber liner for a process chamber having a chamber wall, said chamber liner comprising:
a wall liner having a liner wall including a base portion, a tapered portion extending from said base portion and a neck extending from said tapered portion for engaging the chamber wall.

14. The chamber liner of claim 13 wherein said liner wall has a thickness of about 1 mm to about 3 mm.

15. The chamber liner of claim 13 further comprising a slit interrupting said liner wall of said wall liner.

16. The chamber liner of claim 13 further comprising a slot liner having a slot liner wall for engaging a wafer slot in the chamber wall adjacent to said wall liner.

17. The chamber liner of claim 16 wherein said liner wall of said wall liner and said slot liner wall of said slot liner each comprises anodized aluminum.

18. A method of preventing deposition of polymers on interior wall surfaces of a process chamber having a chamber wall defining a chamber interior and a wafer slot provided in said chamber wall, said method comprising the steps of:
providing a wall liner having a liner wall;
providing a slot liner having a slot liner wall;
inserting said slot liner in said wafer slot of said chamber wall; and
inserting said wall liner in said chamber interior and against said chamber wall.

19. The method of claim 18 wherein said liner wall of said wall liner and said slot liner wall of said slot liner each has a thickness of about 1 mm to about 3 mm.

20. The method of claim 18 further comprising a slit interrupting said liner wall of said wall liner.
